(19) United States
(12) Patent Application Publication
(10) Pub. No.: US 2021/0234063 A1
(43) Pub. Date: Jul. 29, 2021

(54) Broadband Dilute Nitride Light Emitters for Imaging and Sensing Applications

(71) Applicant: Array Photonics, Inc., Tempe, AZ (US)

(72) Inventors: Aymeric MAROS, Tempe, AZ (US); Philip DOWD, Gilbert, AZ (US); Radek ROUCKA, East Palo Alto, CA (US); Sabeur SIALA, Sunnyvale, CA (US)

(21) Appl. No.: 17/156,048

(22) Filed: Jan. 22, 2021

Related U.S. Application Data
(60) Provisional application No. 62/965,401, filed on Jan. 24, 2020.

(51) Int. Cl. H01L 33/00; H01L 33/06; H01L 33/32

(52) U.S. Cl. CPC H01L 33/0045; H01L 33/0025; H01L 33/0075; H01L 33/32; H01L 33/06

(57) ABSTRACT

A stacked superluminescent light-emitting diode having multiple active regions coupled together using and via tunnel junctions. The material compositions of each of the active regions (corresponding quantum wells and/or barriers) differ from one another to provide a controlled different light emission at wavelength (and/or wavelength range) for each junction. In operation of the device, the spectral width of the aggregate light output generated by different junctions is defined by all the junctions, thereby producing a spectrally-broader emission than that of any single, separately taken junction within the device. Thus, the device is configured to operate as a broadband infrared light source.

### CROSS-REFERENCE TO RELATED APPLICATIONS

This application technically relates to the U.S. Provisional Patent Application No. 62/965,401, filed on Jan. 24, 2020, the contents of which are incorporated herein by reference the entirety for all purposes.

### TECHNICAL FIELD

The present invention relates to multiple-junction semiconductor light emitting diodes (LEDs) and superluminescent diodes (SLDs). More particularly, this disclosure relates to semiconductor light-emitting diodes in which the multiple junctions are connected by tunnel junctions, and where the effective bandgaps of different junctions are chosen to be different from one another so as to produce light emissions (light outputs) at different wavelengths from each of the multiple junctions. The combination of light outputs from multiple junctions thereby provides a broadband light source.

### RELATED ART

Broadband infrared light sources have applications including medical imaging, such as optical coherence tomography (OCT), industrial inspection, surveillance, spectral sensing and communications. When compared to narrow linewidth sources such as lasers, broadband light sources offer low coherence length, hence reduced speckle contrast. Light emitting diodes (LEDs) can act as a broadband light emitter. However, these devices typically do not include any optical waveguide, their light emission is spontaneous emission. Although LEDs can provide high power outputs, since the light can be emitted over a wide range of emission angles, the optical power density can be low. Another broadband semiconductor light source is the SLD, which includes an active region (pn-junction) and a waveguide. When the pn-junction of the device is forward biased, light is emitted based on amplified spontaneous emission (ASE) or superluminescence. The device combines the high power and brightness (or power density) of a semiconductor laser diode with the low temporal coherence of semiconductor LEDs. Spatially, the emission can be close to diffraction-limited, i.e., the spatial coherence and beam quality are very high. Therefore, the broadband output can be easily launched into a single-mode fiber. Importantly, SLDs are designed to prevent optical feedback through reflections, in order to prevent lasing from occurring, which would narrow the special emission width. The spectral width or optical bandwidth of a SLD can be between about 25 nm and a maximum value of about 100 nm, with center wavelengths of emission at about 830 nm, 880 nm, 1050 nm, 1310 nm and 1550 nm, depending on the choice of the substrate material and the active region materials that can be grown on the substrate. Consequently, this restricts typical SLDs to limited wavelength ranges only.

In a number of applications, it is preferable to use light at eye-safe wavelengths (those longer than about 1.2 μm, for example, those centered at a center wavelength of about 1400 nm). In some applications, it is also desirable to ensure that a spectral width of the spectrum of light generated by a single light source is greater than 100 nm, with the ultimate goal to produce a single light source with an ultra-broad and continuous spectrum, for practical purposes. Efforts to broaden the optical spectrum in a single light source include changing the material composition of the active layer along the plane of the active layer and utilizing quantum wells of different material composition (and depth) within a single junction. However, the maximum spectral width known thus far has been limited to about 100 nm: the ultimate goal has not been realized yet. Furthermore, as a skilled artisan will readily appreciate, the latter approach of utilizing different quantum wells can cause problems with current injection density and transport of carriers, which can result in unequal filling of adjacent quantum wells in a single junction, thereby affecting the spectral shape of the emission spectrum of the corresponding light source.

It is, therefore, desirable to overcome the limitations causing restrictions on spectral linewidths of existing broadband light sources to provide access to different wavelengths of light and broader spectral linewidths.

### SUMMARY

To overcome the limitations of the spectral width of the light output of existing light sources, LED or SLD structures, or devices with multiple junctions electrically coupled together with the use of tunnel junctions (or tunnels) and capable of producing a combined beam with a broader spectral width are desired.

Embodiments of the invention provide a multi junction SLD structure that includes first and second SLD structures, and a tunnel junction configured to electrically couple the first and second SLD structures. Here, a first material composition of a first quantum well of the first SLD structure and a second material composition of a second quantum well of the second SLD structure are selected such that, in operation of the SLD structure, a first spectrum of a first light output produced by the first SLD structure differs from a second spectrum of a second light output produced by the second SLD structure while, at the same time, a third spectrum that represents a combination of the first and second spectra is caused to be broader than each of the first and second spectra.

In substantially any implementation of the SLD structure, a quantum well of a chosen SLD structure from the first and second SLD structures has a chosen material composition that includes any of InGaAs, InGaAsN, InGaAsSb, InGaAsNSb and GaAsNSb, while a material composition of a quantum well of a SLD structure that is adjacent to such chosen SLD structure differs from the chosen material composition, such that each SLD structure exhibits a different center wavelength. In substantially any implementation, at least one of the first and second SLD structures may include a quantum well structure that contains at least one of a) a quantum well that is substantially nitrogen-free and that has a material composition InₓGa₁₋ₓAs_{1-y}Sb_{y} (with 0≤x≤0.4 and 0≤y≤0.4 and x+y≤0.4) and b) a barrier that includes at least one of GaAs, GaAs_{1-y}N_{y} (with 0<y<0.1, and GaAs_{1-y}P_{y}, where 0<y≤0.35). In such a case, this quantum well structure is characterized by an emission center wavelength in a range from about 900 nm to about 1300 nm, and the center wavelength for each SLD structure differs. In substantially any implementation, at least one of the first and second SLD structures may include an identified quantum well structure that contains at least one of i) a quantum well that is characterized by an emission wavelength and that has a material composition InₓGa₁₋ₓN_{y}As_{1-y-z}Sb_{z} (with either (a) 0≤x≤0.45, 0<y≤0.1, 0≤z≤0.45 and x+z≤0.45, or (b) 0.1≤x≤0.45, 0<y≤0.1, 0≤z≤0.1 and x+z≤0.45) and ii) a barrier that includes at least one of GaAs, GaAs_{1-y}N_{y} (with 0<y<0.1, and GaAs_{1-y}P_{y}, where 0<y≤0.35). In this case, an emission center wavelength of the identified quantum well structure is in a range from about 1100 nm to about 1600 nm, and the center wavelength for each SLD structure differs. Alternatively or in addition, and in substantially any implementation of the SLD structure, at least one of a first In-composition level, a first Sb-composition level, and a first sum of the first In-composition level and the first Sb-composition level of a first active region of the SLD structure may differ from a corresponding at least one of a second In-composition level, a second Sb-composition level, and a second sum of the second In-composition level and the second Sb-composition level a second active region of the SLD structure by a value defined between about 1% and 10%.

Embodiments of the invention additionally provide a multi junction SLD structure that includes first and second SLD structures coupled by a tunnel junction and a lateral confinement region in each of the first and second SLD structures (with such lateral confinement region configured to minimize spatial spreading of current across the SLD structure during operation thereof and to ensure that the current densities in the first and second SLD structures are substantially matched).

Embodiments of the invention additionally provide a methodology for fabricating the multi junction SLD structure. The methodology includes the steps of forming a first SLD structure including a first quantum well; creating a tunnel junction including a second quantum well; and generating a second SLD structure (where the first and second SLD structures are coupled with the tunnel junction). Here, the processes of forming and generating include defining at least one of a first material composition of the first quantum well and a second material composition of the second quantum well to cause the SLD structure to generate, in operation, (i) a first light output produced by the first SLD structure and having a first spectrum and a second light output produced by the second SLD structure and having a second spectrum (where the first and second spectra differ from one another, and where a third spectrum that represents a combination of the first and second spectra is broader than each of the first and second spectra.

### BRIEF DESCRIPTION OF THE DRAWINGS

The following description is made in reference to the drawings that are used for illustration of examples of implementations of the idea of the invention, are generally not to scale, and are not intended to limit the scope of the present disclosure.

FIG. 1 shows a schematic of a multi junction SLD.

FIG. 2 shows a layer structure for a multi junction SLD.

FIG. 3 shows a layer structure for a related embodiment of a multi junction SLD.

FIG. 4 is a band edge diagram representing and corresponding to a single junction of a SLD within a multi junction SLD.

FIG. 5 is a band edge diagram of the multi junction SLDs shown in FIG. 1 and FIG. 3.

FIG. 6 is a plot schematically depicting an emission spectrum of light output produced by a single junction of a SLD within a multi junction SLD.

FIG. 7 is a schematically-drawn emission spectrum characterizing a light output from a multi junction SLD.

FIG. 8 is a schematic of a side view of a multi junction SLD.

FIG. 9 schematically shows a multi junction SLD in a top view.

FIG. 10 shows the top view of a related implementation of a multi junction SLD.

FIG. 11 shows the top view of another multi junction SLD.

FIG. 12 shows the top view of yet another related implementation multi junction SLD.

FIG. 13 is a diagram (shown in a cross-section) of a structure of an embodiment of the multi junction SLD.

FIG. 14 shows a cross-section of a structure of another multi junction SLD having lateral confinement layers.

FIG. 15 illustrates photoluminescence spectra of dilute nitride quantum wells having different Indium-based material compositions.

### DETAILED DESCRIPTION

The following detailed description refers to the accompanying drawings that show, by way of illustration, specific details and examples of embodiments in which the invention may be practiced. Other embodiments may be utilized, and structural, logical, and electrical changes may be made without departing from the scope of the invention. Various embodiments discussed below are not necessarily mutually exclusive, and sometimes can be appropriately combined. The following detailed description is, therefore, not to be taken in a limiting sense, and the scope of the embodiments of the present invention is defined only by the appended claims, along with the full scope of equivalents to which such claims are entitled.

Notwithstanding that the numerical ranges and parameters used in the description are approximations, these numerical values in the specific examples are reported as precisely as possible. Any numerical value, however, inherently contains certain errors necessarily resulting from the standard variation found in their respective testing measurements.

In particular, any numerical range recited herein is intended to include all sub-ranges encompassed therein and are inclusive of the range limits. For example, a range of “1 to 10” is intended to include all sub-ranges between (and including) the recited minimum value of about 1 and the recited maximum value of about 10, that is, having a minimum value equal to or greater than about 1 and a maximum value of equal to or less than about 10.

Also, in this application, the use of “or” means “and/or” unless specifically stated otherwise, even though “and/or” may be explicitly used in certain instances.

The term “lattice-matched”, or similar terms, refer to semiconductor layers for which the in-plane lattice constants of the materials forming the adjoining layers materials (considered in their fully relaxed states) differ by less than 0.6% when the layers are present in thicknesses greater than 100 nm. Further, in devices such as SLDs with multiple layers forming individual regions (such as mirrors, waveguides, or cladding layers) that are substantially lattice-matched to each other in-plane lattice constants may differ by less than 0.6%. Alternatively, the term substantially lattice-matched or “pseudomorphically strained” may refer to the presence of strain within a layer (which may also be thinner than 100 nm), as would be understood from context of the discussion. As such, base material layers, of a given layered structure, can have strain from 0.1% to 6%, from 0.1% to 5%, from 0.1% to 4%, from 0.1 to 3%, from 0.1% to 2%, or from 0.1% to 1%; or can have strain less than 6%, less than 5%, less than 4%, less than 3%, less than 2%, or less than 1%. Layers made of different materials with a lattice parameter difference, such as a pseudomorphically strained layers, can be grown on top of other lattice matched or strained layers without generating misfit dislocations. The term “strain” generally refers to compressive strain and/or to tensile strain.

While the discussion presented below addresses the embodiments of devices formed on a GaAs substrate (or on a substrate that has a lattice constant approximately equal to that for GaAs), the implementation of the idea of invention is not restricted to materials grown on GaAs substrates, but can be applied in principle to devices grown on other semiconductor substrates, including InP and GaSb.

Additionally, while the discussion presented below describes SLDs, the implementation of the idea can apply to LEDs.

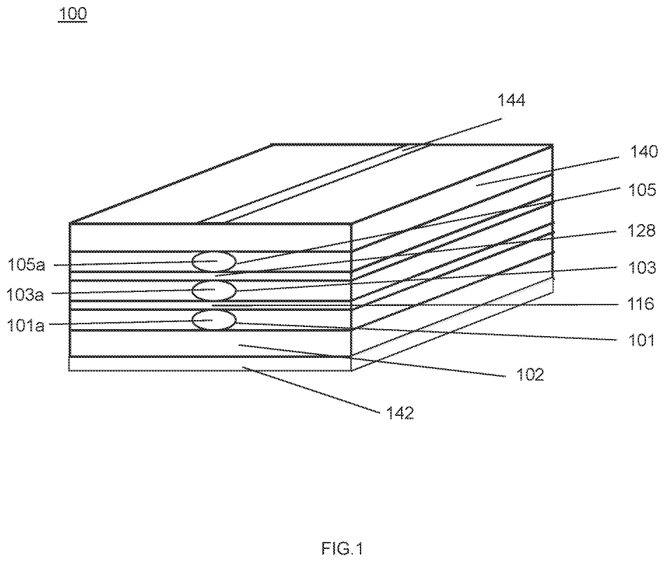

FIG. 1 is a schematic of a multi junction SLD 100. In practice, the layers of the device are deposited epitaxially on a substrate using a semiconductor growth technique such as molecular beam epitaxy (MBE) or metal-organic chemical vapor deposition (MOCVD, or metal-organic chemical vapor deposition, MOVPE, or organometallic vapor phase epitaxy, OMVPE). Hybrid growth, using a combination of both MBE and MOCVD epitaxy to form the device is also possible. The device 100 is shown as having three vertically stacked individual or constituent SLDs that are electrically coupled together using tunnel junctions. According to the idea of the invention, a multi junction SLD such as the device 100, for example, has at least two SLD structures and one tunnel junction. As shown, the device 100 includes a substrate 102, a first SLD structure 101, a first tunnel junction 116, a second SLD structure 103, a second tunnel junction 128, a third SLD structure 105, and a semiconductor contact layer 140. The device 100 also includes a top contact metal member 144 and a bottom contact metal member 142. In one case, the device 100 may be mounted to a heatsink (not shown).

Lateral confinement of current (not shown) may be achieved using standard semiconductor processing techniques. For a stripe contact SLD, this may be achieved, for example, using ion or proton implantation to define high resistivity material regions on either side of the contact metal stripe 144. A buried heterostructure may be created through the process of etching material and subsequent semiconductor regrowth, to define a region through which current flows. Etching and oxidation steps may also be used, as will be described later.

Each SLD structure 101, 103 and 105 in the device 100 is configured to provide, in operation, a corresponding output optical beam (beams 101a, 103a, and 105a, respectively). The optical fields of each of these beams of the stacked SLDs 101, 103, 105 may be spatially coupled together or decoupled as separate beams. This can be achieved by appropriately selecting the compositions and/or thicknesses of material layers that define the SLD and waveguiding structures. Optical beams 101a, 103a and 105a may also be coupled together using external optical components, including lenses, reflectors and/or phase masks.

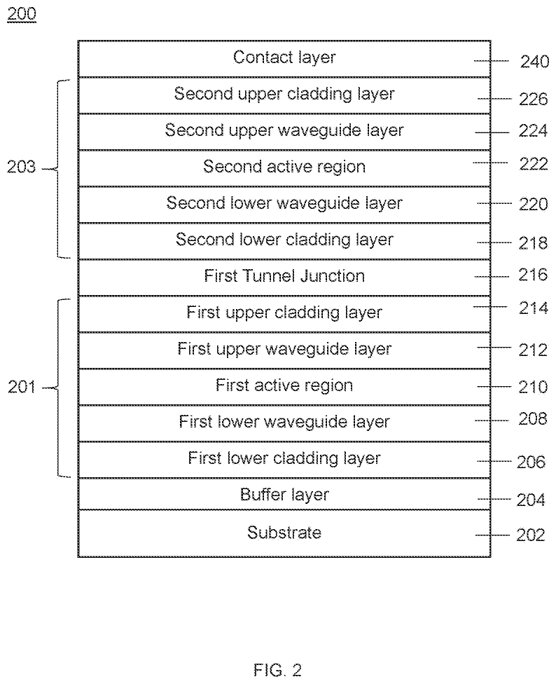

FIG. 2 shows a cross-section of a device 200, providing a more detailed illustration for a semiconductor layer structure of a device with two constituent SLDs and one tunnel junction connecting these SLDs. As shown, the device 200 includes a substrate 202, a buffer layer 204, a first SLD structure 201, a first tunnel junction 216, a second SLD structure 203, and a semiconductor contact layer 140. The first SLD structure 201 includes a first lower cladding layer 206, a first lower waveguide layer 208, a first active region 210, a first upper waveguide layer 212 and a first upper cladding layer 214. The second SLD structure 203 includes a second lower cladding layer 218, a second lower waveguide layer 220, a second active region 222, a second upper waveguide layer 224, and a second upper cladding layer 226. The SLD structures 201 and 203 will be described in more detail later. Each SLD structure forms a corresponding pn-junction.

In one case, the substrate 202 can be configured to have a lattice constant that matches or nearly matches the lattice constant of GaAs or Ge. The substrate can be made of GaAs, for example. The substrate 202 may be doped p-type, or n-type, or may be chosen to be a semi-insulating (SI substrate). The thickness of the substrate 202 can be chosen to be any suitable thickness, typically between about 150 μm and 750 μm. The thickness of the substrate may be reduced (that is the substrate may be thinned) after epitaxial growth to a value of about 50 μm to about 150 Substrate 202 may be configured to include one or more sub-layers, for example, substrate 202 can include epitaxially grown material (such as a ternary or quaternary semiconductor), or be a buffered or composite substrate. In a related case, the substrate 202 can include a Si layer having an overlying SiGeSn buffer layer (which is engineered to have a lattice constant that matches or nearly matches the lattice constant of GaAs or Ge). In this specific case, the substrate 202 can have a lattice parameter different from that of GaAs or Ge by a value that is less than or equal to 3%, preferably less than 1%, or even more preferably less than 0.5%. In substantially any implementation, the lattice constant of the substrate 202 is judiciously chosen to minimize defects in materials subsequently grown thereon.

The device 200 is shown to include a buffer layer 204 overlying (or carried by) and adjacent to the substrate 202. In general, and unless explicitly stated otherwise, as broadly used and described in this application, the reference to a layer or element as being “carried” on a surface of an element or another layer refers to both a layer that is disposed directly on the surface of the element/layer or a layer that is disposed on yet another coating, layer or layers that are disposed directly on the surface of the element/layer. The buffer layer 204 has a lattice constant that matches or nearly matches the lattice constant of the substrate 202. The buffer layer 204 may have the same material doping as that of the substrate, and may be doped p-type, or n-type, or may be semi-insulating. In some embodiments grown on a semi-insulating substrate, the buffer layer 204 may also be doped p-type or n-type dopants in order to facilitate electrical connection in subsequent device processing steps after the overall structure has been grown. The thickness of the buffer layer 204 may be between about 0 and 2 μm. In cases where a GaAs or a Ge substrate 202 is used, the buffer layer 204 can include GaAs, AlGaAs, InGaP, or InAlP.

A first SLD structure 201 overlies the substrate 202 and buffer 204. The SLD structure 201 includes a first lower cladding layer 206 and a first upper cladding layer 214 that sandwich a first lower waveguide layer 208; a first active region 210; and a first upper waveguide layer 212. The bandgap of material(s) that form the cladding layers 206 and 214 is chosen to be higher than that of material(s) employed for waveguiding layers 208 and 212. The refractive index(es) of waveguiding layers 208 and 212 is/are chosen to be higher than the refractive index(es) of the cladding layers 206 and 210. Consequently, the optical spatial mode generated by the SLD structure can be substantially confined to the active region and waveguiding layers. In one implementation, the cladding and waveguiding layers can include AlₓGa₁₋ₓAs, where 0≤x≤1 or AlₓGa₁₋ₓAs_{1-y}P_{y}, where 0≤x≤1 and 0<y≤0.15. The cladding and waveguiding layers may have compositions that differ from each other to produce a desired refractive index and bandgap profile across the structure 200. Using AlₓGa₁₋ₓAs layers as an example, the waveguiding layers may contain less Aluminum than the cladding layers. For example, the waveguiding layers 208 and 212 may be made of GaAs, while the cladding layers 206 and 214 may be made of Al_{0.33}Ga_{0.67}As. The thicknesses of cladding layers 206 and 214, independently, may each be between about 0.5 μm and about 2 μm, and those of the waveguiding layers 208 and 212, independently, may each be between about 100 nm and about 2 μm, or between about 100 nm and about 1 μm, or between about 100 nm and about 0.5 μm, or between about 100 nm and about 250 nm, depending on the specific implementation. In one case, the first lower cladding layer 206 is doped with a dopant of a first type (such as n-type or p-type) with a doping concentration level between about 1×10¹⁷ cm⁻³ and 8×10¹⁸ cm⁻³, or between about 5×10¹⁷ cm⁻³ and 5×10¹⁸ cm⁻³ as an alternative, while the first upper cladding layer 2012 is doped with a dopant of the type that is opposite to the first type (such as p-type or n-type, respectively, in this example) with a doping concentration level between about 1×10¹⁷ cm⁻³ and 8×10¹⁸ cm⁻³, or between about 5×10¹⁷ cm⁻³ and 5×10¹⁸ cm⁻³ as an alternative. Examples of p-type dopants include Be and C. Examples of n-type dopants include Si, Te and Se.

In a specific case, the first lower cladding layer 206 and the first upper cladding layer 214 may have different thicknesses, and/or compositions, and/or doping concentration levels. The first lower cladding layer 206 and the first upper cladding layer 214 may, independently, include sub-layers with different doping levels, and/or compositions and/or thicknesses. The first lower waveguiding layer 208 and the first upper waveguiding layer 212 are, on the other hand, typically undoped. However, in some embodiments at least a portion of the waveguiding layers 208 and 212 may be doped at a doping level lower than about 1×10¹⁷ cm⁻³, in order to reduce series resistance while, at the same time, minimizing waveguide optical losses associated with the presence of the dopant material. The first lower waveguiding layer 208 and first upper waveguiding layer 212, independently, may also have different thicknesses and material compositions, thereby forming an asymmetric waveguide. In some embodiments, a thickness for one of the lower or upper waveguide layers may be about 1 μm and the thickness for the other waveguiding layer may be about 1.5 μm. In other embodiments, the thinner waveguide layer may have a thickness between about 100 nm and 1 μm, and the thicker waveguide layer may have a thickness between about 1 μm and 2 μm. In some embodiments one of the lower or upper waveguides may have a composition AlₓGa₁₋ₓAs while the other waveguide may have a composition of Al_{y}Ga_{1-y}As, where 0≤x≤1 and 0≤y≤1, and x and y are not of the same value, or where 0.1≤x≤0.6 and 0.1≤y≤0.6, and x and y are not of the same value, such as Al_{0.3}Ga_{0.7}As and Al_{0.2}Ga_{0.8}As for example. Such a waveguide can be useful in controlling the spot size of the output beam of a SLD, as well as reducing internal losses, both of which are useful for high power SLD operation. Alternatively, or in addition, the first lower waveguiding layer 208 and first upper waveguiding layer 212 may, independently, include sub-layers with different compositions, and/or doping levels, and/or thicknesses. In a specific case, the first lower waveguiding layer 208 and first upper waveguiding layer 212 may, independently, include layers with substantially continuously graded compositions, where the bandgap monotonically increases away from the active region 210 towards the cladding layer.

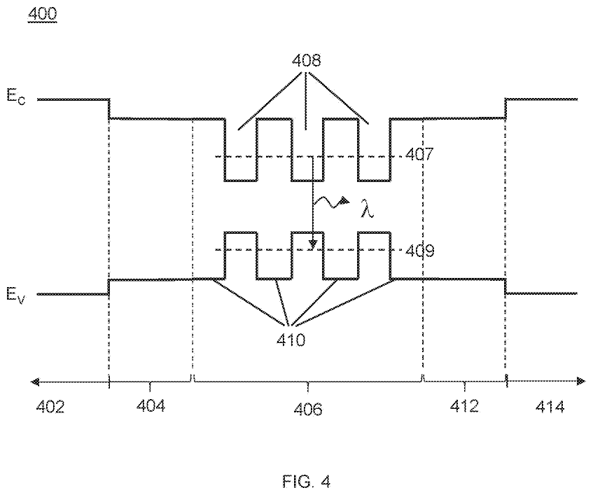

The active region 210 overlies and is adjacent to the first lower waveguiding layer 208 and, at the same time, underlies and is adjacent to the first upper waveguiding layer 212. The active region 210 includes at least one quantum well, formed using a first semiconductor material layer formed between two barrier layers (here, such first semiconductor material layer has a first composition, a first thickness, and a first bandgap while the two barrier layers are made of another semiconductor material having a second composition, a second thickness and a second bandgap, where the second bandgap is larger than the first bandgap). As will be explained in further detail (with respect to FIG. 4), the bandgap of the barrier layers is judiciously chosen to be larger than the bandgap of the quantum well layers in order to provide electrical confinement for both injected electrons and injected holes into the quantum wells. The quantum wells and barriers define an effective bandgap for the active region, which determines the emission wavelength from the SLD structure. Material compositions for the quantum wells may include InGaAs, InGaAsSb, InGaAsN, GaInNAsSb, and GaNAsSb, and the quantum well thicknesses can be between about 5 nm and 12 nm. Depending on a particular implementation. Material compositions for the barrier layers may include any of AlGaAs, GaAs, GaAsN, GaAsP, GaAsN(Sb) and the barrier thickness can be between about 5 nm and 30 nm. Effective bandgaps for the active region can lie between about 0.77 eV and 1.4 eV, corresponding to emission wavelengths between about 900 nm and about 1600 nm.

As shown schematically in FIG. 2, the tunnel junction 216 overlies and is adjacent to the first SLD structure 201. In one example, the tunnel junction 216 includes a thin highly doped n+ layer and a thin highly doped p+ layer adjacent to each other. The n+ layer is adjacent to an n-doped cladding layer of one SLD structure (of the structures 201 and 203), and the p+ layer is adjacent to a p-doped cladding layer of another SLD structure (of the structures 201 and 203) in the device 200. The tunnel junction 216 is configured to electrically connect the SLD structure 201 with the SLD structure 203 in the device 200. When the device 200 is operated under forward bias, a hole-based current flow in the “p” region from one SLD structure is converted into an electron-based current flow in the “n” region of another SLD structure. As a result, a highly conductive, virtually metallic contact junction is established between the vertically neighboring SLD structures 201 and 203. It is required for this purpose that the doping concentrations in the layers of the n+p+ tunnel junction lie in the range of between about 10¹⁹ cm⁻³ and about 10²⁰ cm⁻³. An example of a tunnel junction is provided by a GaAs/AlGaAs tunnel junction, in which each of the GaAs and AlGaAs layers forming such tunnel junction has a thickness between 5 nm and 100 nm. An n-doped GaAs layer can be doped with Te, Se, S and/or Si, and a p-doped AlGaAs layer can be doped with C or Be. In some tunnel junctions, GaAs may be used instead of AlGaAs. In some tunnel junctions, AlGaAs may also be used instead of GaAs. In some tunnel junctions, InGaAs or GaAsSb may also be used instead of GaAs and/or AlGaAs.

As shown, the second SLD structure 203 overlies (is carried by) and is adjacent to the first tunnel junction 216. Here, the second SLD structure 203 is similar to the SLD structure 201, and has a second lower cladding layer 218, a second lower waveguide layer 220, a second active region 222, a second upper waveguide layer 224, and a second upper cladding layer 226. Any of the compositions, and/or thicknesses, and/or doping levels used in the layers (218, 220, 222, 224 and 226) of the SLD structure 203 can differ from those used in the first SLD structure 201 (layers 206, 208, 210, 212 & 214). The compositions and thicknesses can be chosen such that in operation, each SLD emits light over a different wavelength range such that SLD device 200 has a broader emission spectrum than the width of the emission spectrum for each individual SLD structure 201 and 203.

The contact layer 240 overlies and is adjacent to (carried by) the second SLD structure 203. In one embodiment, the contact layer 240 includes a highly doped layer on which a metallic contact layer (not shown in FIG. 2) can be formed. For example, material of the contact layer 240 includes GaAs and has a thickness between about 20 nm and about 250 nm, and a doping concentration level between about 10¹⁹ cm⁻³ and about 10²⁰ cm⁻³.

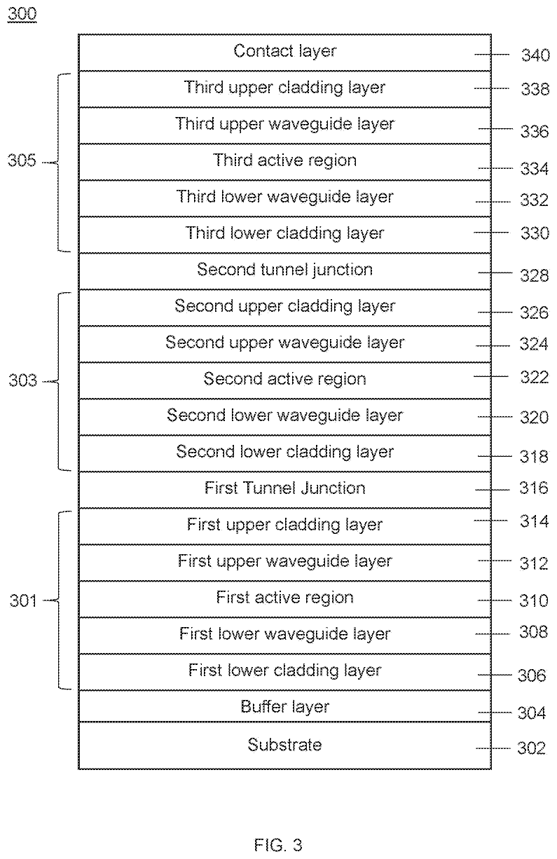

FIG. 3 presents a related embodiment and shows an alternative layer structure 300 configured as the device 100 of FIG. 1. The structure 300 is similar to structure 200 of FIG. 2, but incorporates three constituent SLD structures instead of two. From the comparison of FIGS. 2 and 3 it can be appreciated that here a second tunnel junction 328 is formed or added over the base two-SLD structure (represented by layers 202-226 in FIG. 2, or layers 302-326 in FIG. 3). The material compositions, and/or thicknesses, and/or and doping concentration levels for second tunnel junction 328 may be similar to those for the first tunnel junction (represented by the layer 316 in FIG. 3 or a layer 216 in FIG. 2). A third constituent SLD structure 305 is then formed over the second tunnel junction 328. This third SLD structure 305 is similar to SLD structures 301 and/or 303 (or 201 and 203 of the embodiment of FIG. 2), and has a third lower cladding layer 330, a third lower waveguide layer 332, a third active region 334, a third upper waveguide layer 336, and a third upper cladding layer 338. The overall epitaxial structure of the device 300 is then complemented with the doped semiconductor contact layer 340.

In one implementation, while SLD structures 301, 303 and 205 may be similar, the SLD structures are designed to ensure that in operation, each of these constituent SLDs within the overall SLD device 300 emits light over a different wavelength range such that the combination of wavelength ranges provides a broadband wavelength range for SLD device 300. In another implementation, at least two of the SLD structures are designed such that in operation, the two SLDs within the overall SLD device 300 emits light over a different wavelength range such that the combination of wavelength ranges provides a broadband wavelength range for SLD device 300. A third SLD structure may even be substantially identical (e.g., same material composition) to either of the two SLDs. This may be useful, for example, if the power emitted by a first SLD structure is lower than the power emitted by a second SLD structure. Including a third junction substantially identical to the first SLD enables the power output for the wavelength range emitted by the first SLD structure to be increased. Furthermore, each of the SLD structures also operates with the same injected current density.

Generally, all material layers of embodiments 100, 200 and 300 can be—and preferably are—either lattice matched or pseudomorphically strained to the substrate.

FIG. 4 illustrates the band edge alignment of a single SLD structure 400 used to form a constituent SLD component within an overall device configured according to an embodiment 100, 200 or 300. On this diagram, the conduction band edge is denoted Ec and the valence band edge is denoted Ev. The illustrated band edge alignment could be used, for example, in a constituent SLD (sub)-structure 301, 303 or 305, with the relative band edge positions determined by different material compositions of the layers. The SLD structure 400 includes cladding layers 402 and 414 and waveguide layers 404 and 412. In one implementation, the material compositions, and/or thicknesses, and/or and doping concentration levels of these cladding and waveguide layers can be chosen to be substantially the same as those described above with respect to the embodiment 200 and/or embodiment 300. In one case, the bandgap of the material of the cladding layers is chosen to be larger than the bandgap of the material of the waveguiding layers.

The active region 406 is structured to include a quantum well structure with quantum wells 408 and barrier layers 410. The quantum wells 408 and barrier layers 410 have no intentionally-introduced-doping and are, therefore, undoped or nominally undoped or have a very low background doping level below 1×10¹⁶ cm⁻³. Generally, the active region 406 includes at least one quantum well 408 adjacent to at least two barrier layers 410. In this specific example, as shown, the active region 406 of the embodiment 400 includes three quantum wells 408 and four barrier layers 410, and more generally—in a related embodiment—the active region 406 may be configured to include n quantum wells and n+1 barrier layers, where n is an integer greater than or equal to one. The quantum well(s) 408 have a thickness T_{QW} and a composition C_{QW}, and the barrier layers have a thickness TB and a composition CB. The quantum well structure 406 defines an energy level for confined electrons 407, and an energy level for confined holes 409. The energy separation of these levels (or “effective bandgap”) corresponds to a peak emission wavelength for the quantum well structure. Depending on the specific implementation, the quantum well(s) 408 can be dimensioned to have thicknesses between about 5 nm and about 12 nm. Quantum well(s) 406 can include nitrogen-free materials such as InGaAs, InGaAsSb, and/or GaAsSb, and dilute nitride materials such as InGaAsN, GaInNAsSb, GaNAsSb, GaInNAsBi, and/or GaInNAsSbBi that are either lattice matched or pseudomorphically strained to the substrate. Similarly, in related embodiments the barrier layers 410 can be dimensioned to have thicknesses between about 5 nm and about 30 nm, and can include any of AlGaAs, GaAs, GaAsN, GaAsP, and GaAsN(Sb), that are either lattice-matched or pseudomorphically strained to the substrate. The barrier layers 410 may have more than one sub-layer, with differing material compositions. In one example, the quantum wells may be characterized by compressive strain, while the barrier layers may possess tensile strain to provide a strain-compensated active region that allows for an additional quantum wells to be formed in order to increase the optical gain of the overall embodiment, in operation. The value of the effective bandgap of the active region can be between about 0.77 eV and about 1.4 eV, which corresponds to emission wavelengths in the range from about 900 nm to about 1600 nm.

In at least one case, the quantum wells are structured to be nitrogen-free and have a composition InₓGa₁₋ₓAs_{1-y}Sb_{y}, where 0≤x≤0.4 and 0≤y≤0.4 and x+y≤0.4, while the barriers are configured to include GaAs, GaAs_{1-y}N_{y}, where 0<y≤0.1 and/or GaAs_{1-y}P_{y}, where 0<y≤0.35. The corresponding emission wavelength for the quantum well structures may be between about 900 nm and about 1300 nm. Non-limiting examples of dilute nitride semiconductor quantum well structures are described in U.S. Pat. Nos. 6,798,809 and 7,645,626, the disclosure of each of which is incorporated herein by reference. When dilute nitride quantum wells are employed, these wells may have a material composition InₓGa₁₋ₓN_{y}As_{1-y-z}Sb_{z}, where 0≤x≤0.45, 0<y≤0.1, 0≤z≤0.45 and x+z≤0.45, or where 0.1≤x≤0.45, 0<y≤0.1, 0≤z≤0.1 and x+z≤0.45, while the barriers may include GaAs, GaAs_{1-y}N_{y}, where 0<y≤0.1 or where 0<y≤0.03 and/or GaAs_{1-y}P_{y}, where 0<y≤0.35. The emission wavelength for such quantum well structures may extend from about 1100 nm up to about 1600 nm.

In some cases, where the embodiments 100, 200 and 300 are chosen to include at least two constituent SLD structures or junctions, such embodiments may be formed on a common substrate that is mounted to a heatsink. In other cases, the corresponding layered structures may be “flipped” such that the heatsink is disposed closer to the top-most SLD structure in an epitaxially-grown structure.

In reference to FIG. 4, one junction of the SLD can be configured to have quantum wells with material composition C_{QW1} and thickness T_{QW1}, and barrier layers with material composition C_{B1} and thickness T_{B1}. Another SLD structure of the same device can be configured to have quantum wells with material composition C_{QW2} and thickness T_{QW2}, and barrier layers with material composition C_{B2} and thickness T_{B2}. At least one of material composition and/or thickness differs between the two SLD structures of the same multi junction device.

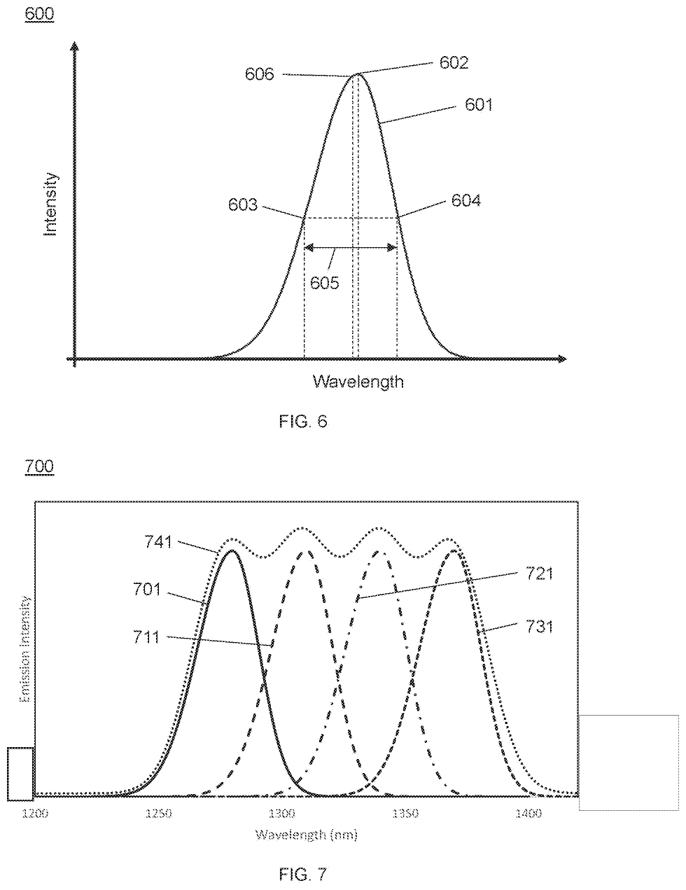

The decision of what the intended and desired difference in the quantum well structure (required to ensure that the difference between the center wavelengths of operation of the different junctions are optimally spectrally spaced) should be depends on and is governed by at least the emission spectral width of each of the junctions. To this end, FIG. 6 illustrates an example of an emission spectrum 601 for a single junction of the multi junction SLD. This emission spectrum is characterized by a peak intensity at peak wavelength 602. Emission spectrum 601 has a full width at half maximum (FWHM) 605, the value of which is conventionally defined by the difference between the two extreme values of the wavelength at which the emission intensity is equal to half of its maximum value. Here, the FWHM 605 is defined by lower value of wavelength 603 and upper value of wavelength 604, at which the intensity values are half the maximum value. Center wavelength 606 is defined as the average of the lower value of wavelength 603 and the upper value of wavelength 604. Depending on the specifics of practical implementation, the FWHM 605 of the emission spectrum 601 may have a value between about 15 nm and about 60 nm (for quantum well active regions on a GaAs substrate). Notably, the value of the FWHM of the emission spectrum may also depend on the electrical current injection into a given SLD, and the FWHM of the spectrum can be defined in terms of its value at the desired injection current range (and power output) for device operation.

It is preferred that the optimal spacing(s) for the center (or peak) wavelengths of adjacent junctions of the multi junction SLD device be approximately equal to the FWHM. Using a FWHM value of 30 nm as a target example, it would be desired that differences in the structures of the neighboring quantum wells result in peak wavelengths (or center wavelengths) that differ by about 30 nm. In related embodiments, the spectral difference between peaks wavelengths of spectral outputs (that have the FWHMs of about 30 nm) produced by neighboring quantum wells of the multi junction SLD and caused by differences of material compositions of these quantum wells, may be between about 27 nm and 33 nm, or between about 25 nm and 35 nm. In a different implementation of the multi junction SLD, for a FWHM value of 20 nm, the difference between the peak (or center) wavelengths of the neighboring quantum wells that is caused by differences in material composition of these wells may be about 20 nm, or between about 18 nm and 22 nm or, between about 16 nm and 24 nm depending on the specifics of implementation.

It is appreciated that for quantum well structures, a 1% change in Indium composition may cause an approximately 7.5 nm to 8.5 nm shift in the peak emission wavelength, while a 1% change in Sb composition may cause a shift on a wavelength of operation by about 6 nm to 7.5 nm. These changes can depend on and vary as a function of the alloy composition. Changes in material strain with changes in material composition can also affect these values. In some examples, changes in peak emission wavelength of up to about 15 nm for a 1% change in composition may be achieved. A decrease in the In and/or Sb composition increases the electron-hole energy separation, thereby decreasing the emission wavelength. Thus, in order to produce the desired change in a bandgap (and associated wavelength shift) between adjacent active regions of the multi junction (stacked) SLD structure, the compositional change required in the quantum well for In, Sb (or a combination of In and Sb) may be in a range between about 1% and about 10%, or between about 1.5% and about 9.3%, or between about 2% and about 8% in a related embodiment, or between about 3% and about 7% in yet another embodiment.

The first SLD structure may have a first active region having a first material composition. The second SLD structure may have a second active region having a second material composition. The second material composition may be different from the first material composition. For example, the second material composition may have a lower percentage % of a certain material than the first material composition.

In one example, the InₓGa₁₋ₓN_{y}As_{1-y-z}Sb_{z} quantum well(s) in a first active region of the multi junction SLD may have an In-composition of about 38% (x=0.38), while a second active region of the same device may have quantum well(s) with an In-composition of, for example, 35% (x=0.35), and a third active region may have quantum well(s) with an even lower In-composition or content (for the purposes of illustration—of 32%; that is x=0.32)). In another example, InₓGa₁₋ₓN_{y}As_{1-y-z}Sb_{z} quantum well(s) in a first active region may be characterized with x=0.37 and z=0.01, where x+z=0.38 (38%), and the quantum well(s) in a second active region may be characterized with x=0.335 and z=0.05, where x+z=0.34 (34%). Therefore, a decrease (or an increase) in the In and/or Sb composition of the quantum wells of an SLD structure can be used to decrease (or increase) the peak emission wavelength of an adjacent quantum well structure by an amount approximately equal to the FWHM of the emission spectrum of a given SLD structure.

Alternatively, or in addition, changes in nitrogen composition or content may also be used to achieve the same goal, with compositional changes between about 0.2% and 1%. For example, a first active region may have quantum well(s) with a nitrogen content of 1% (y=0.01), while a second active region may have quantum well(s) with a nitrogen composition of 1.2% (y=0.012) or 1.5% (y=0.015) or 2% (y=0.02).

As a quantum well corresponding to a given SLD junction decreases in thickness, the energy level separation increases and the corresponding operational wavelength decreases. Thus, the quantum well thickness between adjacent active regions may also be changed to affect the resulting wavelength of operation. Depending on a particular implementation of the idea of the invention, changes in a width of a quantum well (located between adjacent active regions of the multi junction SLD structure) of less than about 2 nm, or less than about 1 nm, or less than about 0.2 nm may be used, with the thinner quantum wells of the multi junction SLD structure producing a shorter peak (or center) wavelength. For example, first quantum wells in a first active region may have thickness(es) of about 8 nm, and second quantum well(s) in a second active region may have thickness(es) of about 7 nm. In other words, the first quantum well(s) and second quantum well(s) may have different thicknesses. In a related implementation, quantum well(s) in a first active region may have thickness(es) of 8 nm and quantum well(s) in a second active region may have thickness(es) of about 7.5 nm, and quantum well(s) in a third active region may have thickness(es) of about 7 nm.

It is appreciated that, in some cases, the barrier thickness and/or material composition may also be judiciously changed to contribute to achieving the same goal of separating the operational wavelengths of the light output (produced by different constituent SLD structures of the same multi junction SLD structure) by the desired spectral distance. In some embodiments, decreases or increases in a barrier width may be less than about 5 nm, or less than about 2 nm, or less than about 1 nm. When GaAs and GaAs_{1-y}N_{y} barrier layers are employed, for example, the change in nitrogen composition of the neighboring barrier layer may be less than about 0.1% (for example, between 1.2% and 1.3%), or less than about 0.2%, or less than about 0.5%, or less than about 1%. Inclusion of nitrogen in a given barrier layer changes the band offsets of the barrier layer with respect to the well, but also decreases the lattice constant, thereby causing tensile strain in the barrier layer material. Notably, this provides additional strain compensation of the compressively strained QWs, thereby also affecting the effective bandgap of the QW structure.

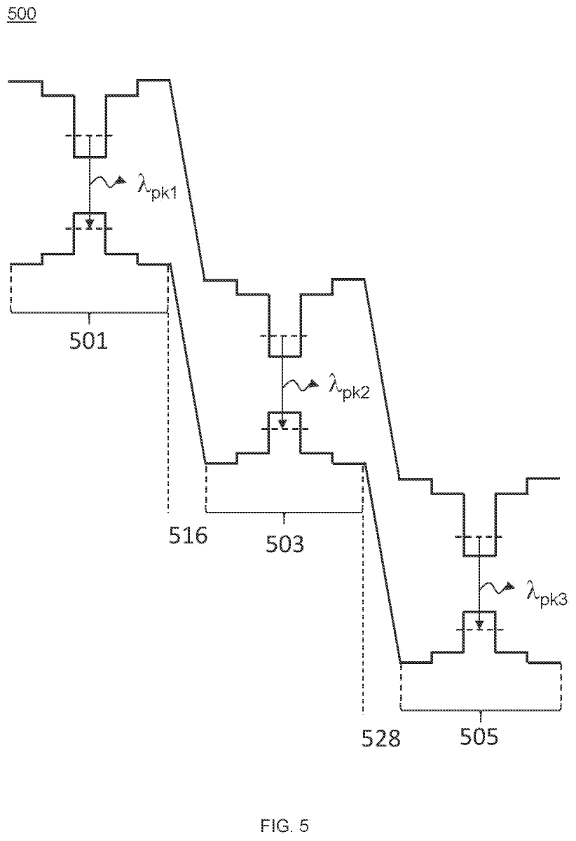

In reference to FIG. 5, an example of an energy band structure 500 of the multiple-junction semiconductor SLD structure of FIG. 1 (configured according to the embodiment 300 of FIG. 3) is shown schematically to include three single junction SLDs respectively having the bands 501, 503 and 505 (corresponding to three SLD structures 301, 303, 305) and connected with the band portions 516, 528 (corresponding to tunnel junctions 316 and 328). The presence of the tunnel junctions in the SLD structure allows for serial electrical connection of the neighboring SLD structures and associated electron-hole conversion. The constituent junction 301, in operation, emits light with a peak wavelength λₚₖ₁, while another constituent junction 303 emits light with a peak wavelength λₚₖ₂, and the constituent junction 305 emits light with a peak wavelength λₚₖ₃. Here, the separations between the peak wavelengths are chosen to be approximately equal to the FWHM of the emission spectrum of light generated by each junction 301, 303, 305.

FIG. 7 shows schematically an emission spectrum from a 4-junction multi junction SLD device configured according to the idea of the invention. The four junctions within the device respectively produce, in operation, first light output with an emission spectrum 701 with a peak wavelength of about 1280 nm and a FWHM of about 30 nm, second light output with an emission spectrum 711 with a peak wavelength of about 1310 nm and a FWHM of about 30 nm, third light output with an emission spectrum 721 with a peak wavelength of about 1340 nm and a FWHM of about 30 nm, and a fourth light output with an emission spectrum 731 with a peak wavelength of about 1370 nm and a FWHM of about 30 nm. The combined, aggregate light output has a spectrum 741 with a FWHM value of about 120 nm and a center wavelength of about 1325 nm. While in this example the combined output spectrum 741 is shown as having an approximate “top-hat” shape, the combined output spectrum of light output produced by the multi junction SLD configured according to the idea of the invention may have other shape(s), such as a Gaussian shape, for example (depending on the number of constituent junctions, as well as the shape and magnitude of each of the individual constituent junctions' spectra). In some embodiments, the multi junction SLD device is configured to have a FWHM of the output spectrum value greater than about 50 nm. In other embodiments, such FWHM is greater than about 100 nm. In other embodiments, where more junctions are stacked together, the FWHM may be greater than about 200 nm, or may be greater than about 400 nm.

FIG. 15 shows the photoluminescence (PL) spectra, measured at room temperature (25° C.), for three sets of dilute nitride quantum wells having different Indium compositions, thereby illustrating the practical implementation of the spectral shift of the output spectrum of the QW-device caused by the variation of the material composition of the QW For QWs with In-concentration between about 24% and 25% (0.24≤x≤0.25), the corresponding PL emission spectrum 1502 had a peak wavelength of about 1340 nm. For QWs with In-concentration between about 27% and 28% (0.27≤x≤0.28), PL spectrum 1504 has a peak wavelength of about 1385 nm. For QWs with In-concentration between about 30% and 31% (0.30≤x≤0.31), PL spectrum 1506 has a peak wavelength of about 1430 nm.

Additional aspects of implementing SLD devices according to the idea of the invention are now discussed in reference to FIGS. 8, 9, and 10. FIG. 8 shows a side view of a multi junction SLD 800. Device 800 includes a substrate 802, a first SLD structure 804 with a first active region 806, a tunnel junction 808, a second SLD structure 810 with a second active region 812, an upper metal contact layer 814, a lower metal contact layer 816. The device 800 may be cleaved, to form constituent SLDs with facets along the cleaved planes that are respectively coated with a first facet coating 818 and a second facet coating 820. In some embodiments, at least one of first facet coating 818 and second facet coating is an anti-reflection coating, judiciously designed in order to suppress feedback of reflected light and hence suppress potential lasing behavior. In some embodiments, both facet coatings 818, 820 are anti-reflection coatings. Anti-reflection coatings are known and may comprise dielectric layers such as silicon oxide, silicon nitride, aluminum oxide, and the like. Light generated by active regions 806 and 812 of constituent SLD structures 804 and 810 may be emitted through both facets of the device, and may be appropriately combined into an output beam 801 and output beam 803. In order to increase the power emitted from one facet and to minimize the power emitted from the other facet, in some embodiments, either facet coating 818 or facet coating 820 is a high-reflectivity dielectric coating. In such an embodiment, light is emitted through the facet with the antireflection coating, while light emission is reduced or suppressed at the facet with the high-reflectivity dielectric coating. In some embodiments, the facet may further be polished or etched (such as by reactive ion etching or chemically assisted ion beam etching or focused ion beam etching) to produce an angle between the end of the current stripe (or the cleaved plane of the device) and the facet between about 7 and 12 degrees.

FIG. 9 shows, in a top view, a multi junction SLD 900 that has an angled top contact metal stripe 914, a first facet coating 918 and a second facet coating 920, similar to facet coatings 818 and 820 in FIG. 8. The angled stripe provides current injection, and hence gain along the stripe, but since the stripe is angled with respect to the facets (with facet coatings 918 and 920), the angle further reduces optical feedback. As with device 800 in FIG. 8, light may be emitted from one or both facets (beam 901, beam 903). The angle θ at which the stripe intersects the facet may be between about 7 and 12 degrees.

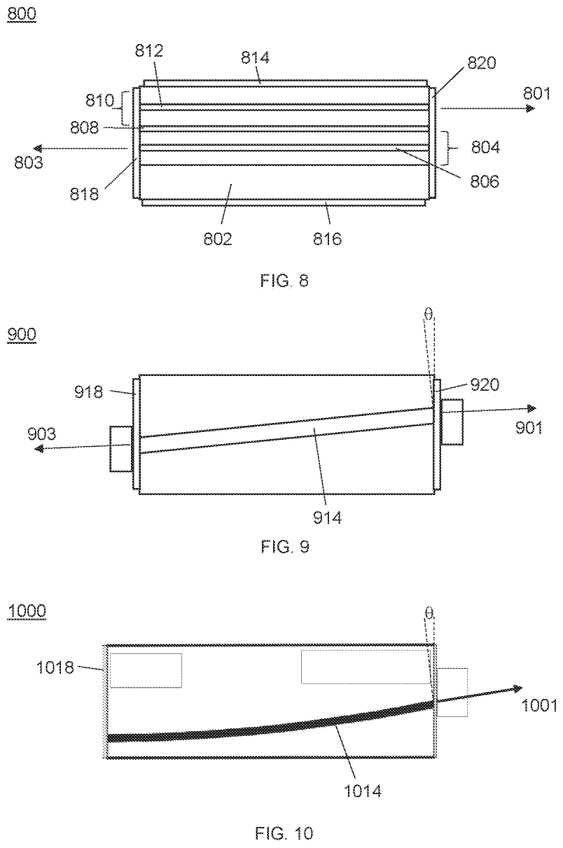

FIG. 10 shows a top view of a multi junction SLD 1000 having a curved top contact metal stripe 1014, and a first facet coating 1018. The curved stripe provides current injection, and hence gain along the strip, but as with device 900, the stripe is not orthogonal to the emission facet, which reduces optical feedback. The angle θ at which the stripe intersects the facet may be between about 7 and 12 degrees. First facet coating 1018 is a high reflectivity coating that prevents or reduces light emission from that facet, resulting in a single light output beam 1001.

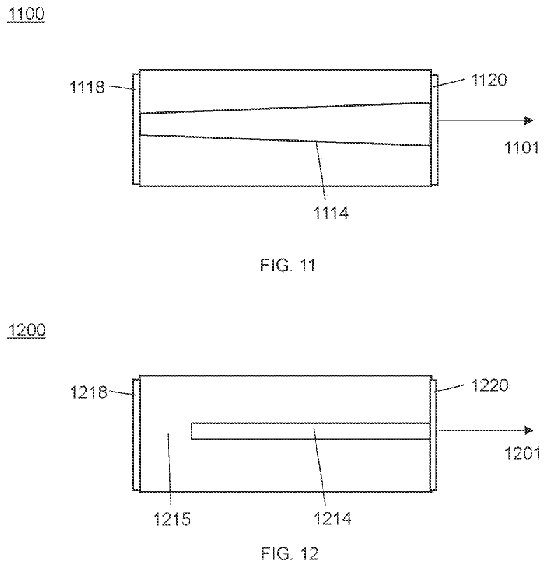

FIG. 11 shows a top view of another multi junction SLD 1100 having a tapered top contact metal stripe 1114, a high reflectivity coating 1118 and an antireflection coating 1120. The tapered stripe provides gain along the stripe, and the broader area of the strip at one facet, with antireflection coating 1120 provides a larger emission area for emitted light beam 1101.

FIG. 12 shows a top view of another multi junction SLD 1200 having a current injection strip 1214, an absorber region 1215, first facet coating 1218 and second facet coating 1220. Current stripe 1214 provides current injection, and hence gain along the stripe. However, current stripe 1214 does not run along the entire length of the SLD 1200. Current stripe 1214 extends across at least 50% of the length of the SLD. At the end of the SLD where the current stripe 1214 is not present, there is no gain and an absorbing region 1215 forms between the end of the SLD and the end of the metal stripe. The absorbing region therefore introduces losses and hence suppresses optical feedback from one facet of the device. In some embodiments, a small absorbing region (not shown) can exist at the emitting facet region (between stripe 1214 and facet coating 1220), further suppressing optical feedback. If present, the length of this small absorbing region can be between about 1 μm and 10 Second facet coating 1220 is a dielectric anti-reflection coating similar to anti-reflection coatings 816 and 916 for devices 800 and 900 in FIGS. 8 and 9. Light is emitted through second facet coating 1220 (beam 1201).

Another problem recognized in operation of a SLD device with stacked (multiple) SLD structures is caused by the fact that the current required to reach a “threshold” value can differ for each constituent SLD. Unlike a laser diode, an SLD does not have a sharp distinct threshold current above which stimulated emission occurs, but the output intensity gradually increases with current. A soft knee in the light-current characteristic defines the point at which light emission transitions from a spontaneous emission regime to amplified spontaneous emission (or superluminescent) regime, and this operating point may be referred to as the threshold current. If the threshold current for each of the SLD structures differs, this can result in non-linear light-current characteristics, and widely varying spectral bandwidth as a function of the current. The threshold current values can differ for different junctions due to several reasons. Firstly, lateral current spreading can affect injected current density at the different junctions, and, as a result, the threshold current density may not be reached in each and every constituent SLD of the overall multi junction SLD system under a given operating current—thus superluminescence might not occur in all junctions at the same time. There may also be additional losses associated with a given junction (such as surface recombination losses and/or optical losses related to highly doped layers such as contact layers and tunnel junction layers located in close proximity to the SLD active regions). These shortcomings may be compensated for “vertically” (using different waveguide designs for each constituent SLD sub-structure within the overall device) and/or “laterally” (through the use of appropriate confinement structures). The waveguide design for each junction can be adjusted, for example, to judiciously change the overlap between the optical field and the active region for each SLD sub-structure, thereby changing the effective gain between the different SLD sub-structures. This result can be achieved using different compositions and/or thicknesses for the waveguide layers and cladding layers for each of the junctions, providing a different refractive index profile and hence optical mode profile for each of the SLD structures. (Such approach can be used, for example, to decrease the gain of a SLD structure that has the lowest threshold current in order to match it to the threshold current of another SLD structure within the device.

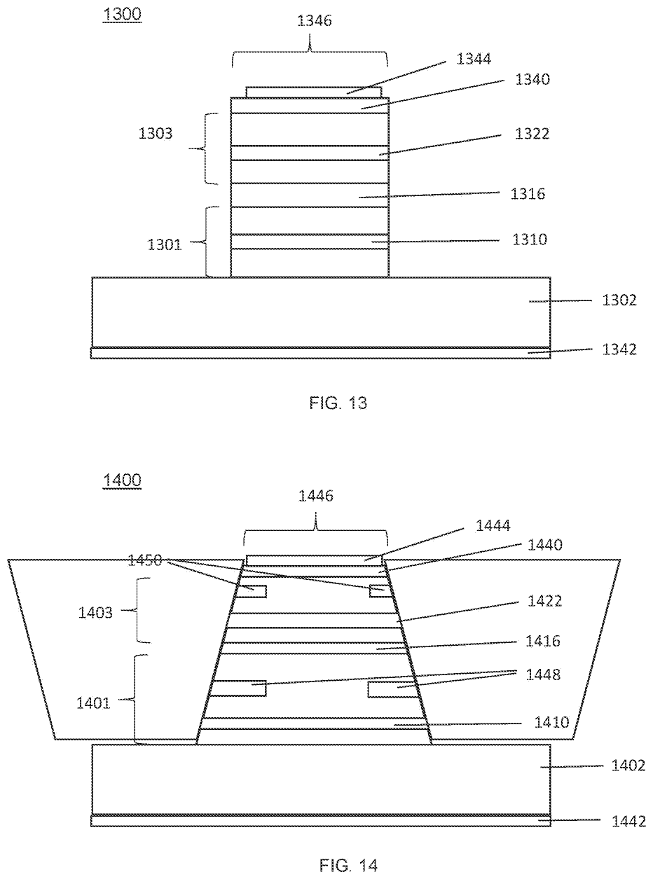

FIG. 13 shows a cross-section of a stacked multi junction SLD device 1300 with an etched stripe. The etch stripe has a width 1346. The embodiment 1300 includes a substrate and buffer 1302, a bottom SLD structure 1301 with an active region 1310, a tunnel junction 1316, a top SLD structure 1303 with an active region 1322, a contact layer 1340, a lower contact metal layer 1342, and upper contact metal layer 1344. The device 1300 may include other auxiliary layers (not shown) such as, for example, a passivation layer to reduce surface losses associated with the etched sidewalls, and facet-coatings such as anti-reflection coatings. Passivation layers and facet coatings are known and may include dielectric materials including silicon oxide, silicon nitride and Al₂O₃. In the device as shown, the threshold currents for the two constituent SLD structures 1301, 1303 could be expected to be substantially equal, as there is no spatial current spreading. However, during the etching process to form the ridge or stripe 1346, the sidewalls of the upper SLD structure 1303 are necessarily exposed to the etching environment for a time longer than the time of exposure to the same environment of the SLD structure 1301. This may increase the rate of surface recombination at the junction of the upper SLD 1303 as compared to the junction of the lower SLD 1201, thereby resulting in a higher threshold current for the upper SLD 1303. By reducing the waveguiding effect on the junction of the lower SLD structure 1301, its threshold current can be appropriately increased to match the threshold current of the top SLD structure 1303.

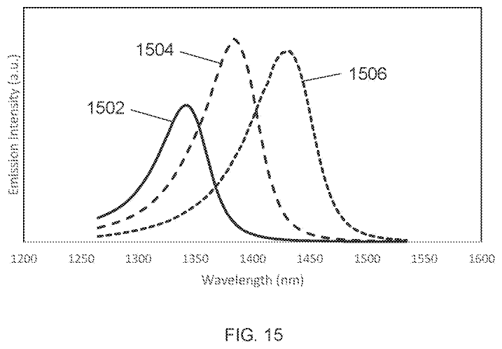

FIG. 14 provides another example of a SLD device 1400 with an etched ridge or stripe 1446, where there is a variation of the stripe width as a function of depth (or height of the stripe). The etch stripe 1446 has a smaller width at the top and can be broader at the base of the etched stripe. The difference in geometrical parameters of the stripe 1446 as a function of its height can lead to current spreading, which process reduces the current density for SLD structures located at spatially-lower levels of the device 1400. Design of the waveguiding structure may not be able to completely compensate for this effect, hence the addition used of lateral confinement structures can be employed to control the active width and volume of the current injection region in each of the present SLD structures. The SLD device embodiment 1400 includes a substrate and buffer 1402, a bottom SLD structure 1401 with an active region 1410, a tunnel junction 1416, a top or upper SLD structure 1403 with an active region 1422, a contact layer 1440, a lower metal 1442, and an upper or top metal contact layer 1444. The device 1400 also includes a first current confinement region 1448 for a constituent SLD structure 1401 (defining a first width of a region associated with the current injection) and a second confinement region 1450 for a constituent SLD structure 1403 (defining a second width of a region associated with the current injection). The first width may be different (e.g., larger) than the second width.

Device 1400 may include other, auxiliary layers (not shown) such as a facet coating or a passivation layer, for example, to reduce surface losses associated with the etched sidewalls of the ridge 1446, and to protect surfaces of layers during an oxidation process step, to prevent oxidation of layers other than the layers to be oxidized to form the confinement layers. Passivation layers are known to include, for example, dielectric materials such as silicon oxide, silicon nitride and Al₂O₃. First and second confinement regions 1448 and 1450 can be formed in a cladding layer for each of the SLD structures with the use of ion or proton implantation and/or selective oxidation. The process of ion implantation produces a highly resistive region, while defining the low resistivity region through which current can flow. In the embodiment 1400, two different implant depths may be required and so ion implantation may need to take place at two different energy levels.

The oxide confinement process produces a highly resistive region by selective oxidation of a high aluminum-content layers using known methods. For devices formed on GaAs substrate, the layer or layers for oxidation typically include Al_{y}Ga_{1-y}As, where y is greater than 0.9. The oxidation process forms confinement region that has (a) a low refractive index and (b) high resistivity, when compared to the unoxidized region of material, and therefore provides both optical and electrical confinement. Since the width of the etch stripe varies as a function of depth, different oxidation lengths are required for each confinement region in order to produce the desired current confinement. The oxidation rate for an oxidation layer is dependent on the composition of the layer and the thickness of the layer. Thus, the thickness and/or composition for confinement regions 1448 and 1450 may be required to differ in order to provide the same current confinement effect for each SLD structure.

Additionally, for at least one of the SLD structures (and, in one case, for each SLD structure), an Al_{y}Ga_{1-y}As oxidation layer can be grown as a part of the cladding layer for such junction, where y>0.9 or y>0.97. The thickness of the oxidation layer, if so formed, can be between about 10 nm and about 70 nm. Notably, the oxidation rate for a layer with a higher Al content is higher than for a layer with lower Al content. The oxidation rate also increases with increasing layer thickness. Therefore, based on the knowledge or assessment of the etch stripe geometry and the desired oxidation length for the oxidation layer for a given SLD structure, the composition and/or thickness of the corresponding confinement layer can be chosen so as to produce different oxidation lengths in a single-step oxidation process (with the process controlling the confining width to be the same for more than one junction). This operation can result in matching the current density between junctions to within 1%, or at least within 2%, or at least within 5% depending on the details of a particular implementation. In the case of the embodiment 1400, the oxidation length required for the SLD structure 1401 is greater than the oxidation length required for the SLD structure 1403. Therefore, the confinement region 1448 can have a higher Al content than the confinement region 1450, while having the same thickness as that of the confinement region 1450. Alternatively, and in a related embodiment, the confinement region 1448 can also be thicker than the confinement region 1450, while having the same material composition as that of the confinement region 1450. In yet another related embodiment, a combination of different compositions and thicknesses for these confinement layers may also be used.

Standard oxidation process calibration procedures can be used to determine the oxidation rates for AlGaAs materials, and therefore to determine the composition and thickness of the oxidation layer(s) required for a given etch process. For a device with a uniform etch stripe width, the confinement region composition and/or thickness may also differ to compensate for differing threshold conditions for the different SLD structures of the device, thereby ensuring the threshold carrier concentration required for each of the multiple junctions is achieved for the same (substantially equal for every junction) current injection level.

To fabricate embodiments of semiconductor optoelectronic devices structured according to the idea of the invention, a plurality of layers can be deposited on an appropriate substrate in a first-materials-deposition chamber. Such plurality of layers may include etch-stop layers; release layers (i.e., layers designed to release the semiconductor layers from the substrate when a specific process sequence, such as chemical etching, is applied); contact layers such as lateral conduction layers; buffer layers; layers forming reflectors or mirror structures, and/or or other semiconductor layers. For example, the sequence of layers deposited on the substrate in the first-materials-deposition chamber can include buffer layer(s), then a lateral conduction or contact layer(s). Next, the substrate can be transferred to a second-materials-deposition chamber, where a waveguide region or confinement region and an active region are formed on top of the existing, already-deposited semiconductor layers. The substrate may then be transferred to either the first-materials-deposition chamber or to a third-materials-deposition chamber for deposition of additional layer(s) such as contact layers. Tunnel junctions may also be formed, in some implementations.

The movement or repositioning/relocation of the substrate and semiconductor layers from one deposition chamber to another chamber is referred to as transfer. The transfer may be carried out in vacuum, at atmospheric pressure in air or another gaseous environment, or in an environment having mixed characteristics. The transfer may further be organized between materials deposition chambers in one location, which may or may not be interconnected in some way, or may involve transporting the substrate and semiconductor layers between different locations, which is known as transport. Transport may be done with the substrate and semiconductor layers sealed under vacuum, surrounded by nitrogen or another gas, or surrounded by air. Additional semiconductor, insulating or other layers may be used as surface protection during transfer or transport, and removed after transfer or transport before further deposition.

For example, a dilute nitride active region and waveguiding region can be deposited in a first-materials-deposition chamber, while the AlGaAs/GaAs cladding and other structural layers can be deposited in a second-materials-deposition chamber. To fabricate edge emitting devices discussed in this disclosure, some or all of the layers of the active region, including a dilute nitride based active region can be deposited with the use of molecular beam epitaxy (MBE) on one deposition chamber, and the remaining layers of the SLD can be deposited with the use of chemical vapor deposition (CVD) in another materials deposition chamber.

In some embodiments, a surfactant, such as Sb or Bi, may be used when depositing any of the layers of the device. A small fraction of the surfactant may also incorporate within a layer.

A semiconductor device comprising a dilute nitride layer can be subjected to one or more thermal annealing treatments after growth. For example, a thermal annealing treatment includes the application of a temperature in a range from about 400° C. to about 1,000° C. for a duration between about 10 microseconds and about 10 hours. Thermal annealing may be performed in an atmosphere that includes air, nitrogen, arsenic, arsine, phosphorus, phosphine, hydrogen, forming gas, oxygen, helium, or any combination of the preceding materials.

Additional structural features of an embodiment of the SLD device of the invention may be chosen to be similar to those described in the U.S. Provisional Patent Application No. 62/953,253. The invention as recited in claims appended to this disclosure is intended to be assessed in light of the disclosure as a whole, including features disclosed in prior art to which reference is made.

For the purposes of this disclosure and the appended claims, the use of the terms “substantially”, “approximately”, “about” and similar terms in reference to a descriptor of a value, element, property or characteristic at hand is intended to emphasize that the value, element, property, or characteristic referred to, while not necessarily being exactly as stated, would nevertheless be considered, for practical purposes, as stated by a person of skill in the art. These terms, as applied to a specified characteristic or quality descriptor means “mostly”, “mainly”, “considerably”, “by and large”, “essentially”, “to great or significant extent”, “largely but not necessarily wholly the same” such as to reasonably denote language of approximation and describe the specified characteristic or descriptor so that its scope would be understood by a person of ordinary skill in the art. In one specific case, the terms “approximately”, “substantially”, and “about”, when used in reference to a numerical value, represent a range of plus or minus 20% with respect to the specified value, more preferably plus or minus 10%, even more preferably plus or minus 5%, most preferably plus or minus 2% with respect to the specified value. As a non-limiting example, two values being “substantially equal” to one another implies that the difference between the two values may be within the range of +/−20% of the value itself, preferably within the +/−10% range of the value itself, more preferably within the range of +/−5% of the value itself, and even more preferably within the range of +1-2% or less of the value itself. The term “substantially equivalent” may be used in the same fashion. In a specific example, when two wavelengths are stated to substantially coincide, the substantial coincidence is defined as and implies that the wavelengths at hand do not differ from one another by more than 5 nm, preferably by not more than 2 nm, even more preferably by not more than 1 nm.

The use of these terms in describing a chosen characteristic or concept neither implies nor provides any basis for indefiniteness and for adding a numerical limitation to the specified characteristic or descriptor. As understood by a skilled artisan, the practical deviation of the exact value or characteristic of such value, element, or property from that stated falls and may vary within a numerical range defined by an experimental measurement error that is typical when using a measurement method accepted in the art for such purposes.

Although specific embodiments have been illustrated and described herein, it will be appreciated by those of ordinary skill in the art that any arrangement that is calculated to achieve the same purpose may be substituted for the specific embodiments shown. This application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present invention includes any other applications in which embodiment of the above structures and fabrication methods are used. The scope of the embodiments of the present invention should be determined with reference to claims associated with these embodiments, along with the full scope of equivalents to which such claims are entitled.

1. A multi junction superluminescent diode (SLD) structure, comprising:
a first SLD structure producing a first light output having a first spectrum when in operation;
a second SLD structure producing a second light output having a second spectrum when in operation; and
a first tunnel junction coupling the first SLD structure and the second SLD structure,
wherein the first spectrum differs from the second spectrum,
wherein the multi junction edge emitting SLD structure produces a third light output having a third spectrum, the third spectrum representing a combination of the first spectrum and the second spectrum and is broader than each of the first spectrum and the second spectrum.

2. The multi junction SLD structure of claim 1, wherein the first spectrum includes a first central wavelength, and the second spectrum includes a second central wavelength,
wherein a spectral difference between the first central wavelength and the second central wavelength is approximately equal to a spectral width of the first spectrum or the second spectrum.

3. The multi junction SLD structure of claim 1, wherein a quantum well of a chosen SLD structure from the first and second SLD structures has a chosen material composition comprising any of InGaAs, InGaAsN, InGaAsSb, InGaAsNSb, and GaAsNSb, while a material composition of a quantum well of a SLD structure that is adjacent to the chosen SLD structure differs from the chosen material composition.

4. The multi junction SLD structure of claim 1, wherein at least one of the first and second SLD structures includes a quantum well structure that contains at least one of:
i) a quantum well that has a material composition InₓGa₁₋ₓN_{y}As_{1-y-z}Sb_{z}, wherein either (a) 0≤x≤0.45, 0<y≤0.1, 0≤z≤0.45 and x+z≤0.45, or (b) 0.1≤x≤0.45, 0<y≤0.1, 0≤z≤0.1, and x+z≤0.45, and
ii) a barrier layer that includes at least one of:
GaAs and GaAs_{1-y}N_{y}, wherein 0<y<0.1; and
GaAs_{1-y}P_{y}, wherein 0<y≤0.35, and
wherein an emission wavelength of the quantum well structure is in a range from about 1100 nm and about 1600 nm.

5. The multi junction SLD structure of claim 1, wherein at least one of:
a first In-composition level, a first Sb-composition level, and a first sum of the first In-composition level and the first Sb-composition level of a first active region of the first SLD structure differs from a corresponding at least one of:
a second In-composition level, a second Sb-composition level, and a second sum of the second In-composition level and the second Sb-composition level of a second active region of the second SLD structure by a value between 1% and 10%.

6. The multi junction SLD structure of claim 1, further comprising:
a third SLD structure producing a fourth light output having a fourth spectrum when in operation; and
a second tunnel junction configured to couple the second SLD structure and the third SLD structure.

7. The multi junction SLD structure of claim 6, wherein the third SLD structure is substantially identical to the first SLD structure, and a power of the first spectrum is lower than a power of the second spectrum.

8. The multi junction SLD structure of claim 1, wherein the first SLD structure comprises a first quantum well structure, the first quantum well structure including one or more quantum wells and one or more barrier layers,
wherein the one or more quantum wells comprise InGaAs, InGaAsSb, GaAsSb, InGaAsN, GaInNAsSb, GaNAsSb, GaInNAsBi, or GaInNAsSbBi,
wherein the one or more barrier layers comprise AlGaAs, GaAs, GaAsN, GaAsP, or GaAsN(Sb).

9. The multi junction SLD structure of claim 1, wherein the first SLD structure comprises a first active region, the first active region having an effective bandgap between about 0.77 eV and about 1.4 eV.

10. The multi junction SLD structure of claim 1, wherein the first SLD structure comprises a first active region having a first percentage of a material, and the second SLD structure comprises a second active region having a second percentage of the material, wherein the first percentage is different from the second percentage.

11. The multi junction SLD structure of claim 1, wherein the first SLD structure comprises a first active region having one or more first quantum wells each having a first thickness, and the second SLD structure comprises a second active region having one or more second quantum wells each having a second thickness, wherein the first thickness is different from the second thickness.

12. The multi junction SLD structure of claim 1, wherein the multi junction SLD structure is an edge-emitting device.

13. The multi junction SLD structure of claim 1, wherein the third light output has a spectral bandwidth of at least 100 nm.

14. A multi junction SLD structure comprising:
a first SLD structure having a first threshold current density;
a second SLD having a second threshold current density; and
a first tunnel junction coupling the first SLD structure and the second SLD structure,
wherein each of the first and second SLD structures includes one or more confinement regions, the one or more confinement regions configured to minimize spatial spreading of current across the respective SLD structure during operation thereof,
wherein during operation, the first threshold current density and the second threshold current density are substantially matched.

15. The multi junction SLD structure of claim 14, wherein the one or more confinement regions of the first SLD structure has a first width, and the one or more confinement regions of the second SLD structure has a second width, the first width is different from the second width.

16. A method for fabricating a multi junction edge-emitting SLD structure, the method comprising:
forming a first SLD structure including a first quantum well;
creating a tunnel junction including a second quantum well; and
generating a second SLD structure, wherein the first and second SLD structures are coupled with the tunnel junction;
wherein the forming and the generating includes defining at least one of a first material composition of the first quantum well and a second material composition of the second quantum well to cause the SLD structure to generate, in operation:
a first light output produced by the first SLD structure and having a first spectrum, and
a second light output produced by the second SLD structure and having a second spectrum,
wherein the first spectrum and the second spectrum differ from one another, and
wherein a third spectrum that represents a combination of the first and second spectra is broader than each of the first spectrum and the second spectrum.

17. The method of claim 16, wherein the forming, the creating, and the generating includes defining at least one of the first material composition, the second material composition, and a material composition of the tunnel junction to cause a spectral difference between a first central wavelength of the first spectrum and a second central wavelength the second spectrum to be approximately equal to a spectral width of one of the first spectrum and the second spectrum.

18. The method of claim 17, wherein the defining includes defining a chosen material composition of a quantum well of a chosen SLD structure from the first SLD structure and the second SLD structure to include any of InGaAs, InGaAsN, InGaAsSb, InGaAsNSb and GaAsNSb, while defining a material composition of a quantum well of a SLD structure that is adjacent to the chosen SLD structure to differ from the chosen material composition;

19. The method of claim 17, wherein the defining includes structuring at least one of the first SLD structure and the second SLD structure to include an identified quantum well structure that includes at least one of:
i) a quantum well that has a material composition InₓGa₁₋ₓN_{y}As_{1-y-z}Sb_{z}, wherein either:
(a) 0≤x≤0.45, 0<y≤0.1, 0≤z≤0.45, and x+z≤0.45; or
(b) 0.1≤x≤0.45, 0<y≤0.1, 0≤z≤0.1, and x+z≤0.45; and
ii) a barrier layer that includes at least one of:
GaAs and GaAs_{1-y}N_{y}, wherein 0<y<0.1; and
GaAs_{1-y}P_{y}, wherein 0<y≤0.35,
to cause an emission wavelength of the identified quantum well structure to be, in operation of the chosen SLD structure, in a range from about 1100 nm and about 1600 nm; and

20. The method of claim 17, wherein the defining includes causing at least one of a first In-composition level, a first Sb-composition level, and a first sum of the first In-composition level and the first Sb-composition level of a first active region of the chosen SLD structure to differ from a corresponding at least one of a second In-composition level, a second Sb-composition level, and a second sum of the second In-composition level and the second Sb-composition level of a second active region of the laser structure by a value between 1% and 10%.
